(19) United States
(12) Patent Application Publication
(10) Pub. No.: US 2012/0112740 A1
(43) Pub. Date: May 10, 2012

(54) HALL DEVICE MODULE EQUIPPED WITH INTERCONNECTED DOUBLE HALL DEVICES

(75) Inventors: Dong Ok HAN, Suwon (KR); Sang Gyu PARK, Anyang (KR)

(73) Assignee: SAMSUNG ELECTRO-MECHANICS CO., LTD., Suwon (KR)

(21) Appl. No.: 13/024,049

(22) Filed: Feb. 9, 2011

(30) Foreign Application Priority Data
Nov. 4, 2010 (KR) 10-2010-0109311

(51) Int. Cl. G01R 33/07

(52) U.S. Cl. 324/251

(57) ABSTRACT

There is provided a hall device module equipped with interconnected double hall devices. The hall device module includes: a first hall device having a first pair of terminals for excitation and a pair of output terminals; and a second hall device having a second pair of terminals for excitation and a pair of output terminals, wherein the first and second hall devices have the same equivalent circuit, the second hall device is disposed to be rotated by a predetermined angle based on the first hall device, a first terminal of the first pair of terminals is interconnected to a first terminal of the second pair of terminals to receive driving power for excitation, a second terminal of the first pair of terminals is interconnected to a second terminal of the second pair of terminals and is grounded, terminals outputting a positive component, which is a voltage rising according to an applied external magnetic field, among the pair of output terminals of the first hall device and the pair of output terminals of the second hall device, are interconnected, and terminals outputting a negative component, which is a voltage falling according to the applied external magnetic field, are interconnected, to thereby remove an offset.

### CROSS-REFERENCE TO RELATED APPLICATIONS

This application claims the priority of Korean Patent Application No. 10-2010-0109311 filed on Nov. 4, 2010, in the Korean Intellectual Property Office, the disclosure of which is incorporated herein by reference.

### BACKGROUND OF THE INVENTION

1. Field of the Invention

The present invention relates to the offset removal of hall devices, and more particularly, to a hall device module equipped with interconnected double hall devices capable of removing the offset of the hall devices by rotating one of two hall devices, manufactured under the same condition to be represented by the same equivalent circuit, by 90 degrees with relation to the other hall device and interconnecting these two hall devices.

2. Description of the Related Art

Generally, a hall device is a device sensing a magnetic field using a hall effect. The ‘hall effect’ is evident when, in the case that a magnetic field is applied to any conductor through which current flows, a force (Lorentz's force) is generated in a predetermined direction, the flow of the current changes due to the force, and a difference in voltages at two detection ends is generated by the change in the flow of the current. The hall device should output a hall voltage of zero when there is no external magnetic field, and should output voltage as high as possible for high sensitivity when there is an external magnetic field. In order to improve the characteristics of the hall device, a specialized hall device is being developed by adjusting various forms, processes, doping concentrations, or the like.

Meanwhile, the hall device may not generate distortion such as offset or temperature; however, the hall device may output an offset having a predetermined voltage magnitude rather than zero voltage due to several factors such as a manufacturing technology, a manufacturing process, and the like. When the offset is generated in the hall device, the sensitivity of a hall sensor is deteriorated by the magnitude of the offset.

### SUMMARY OF THE INVENTION

An aspect of the present invention provides a hall device module capable of removing the offset of hall devices.

Another aspect of the present invention provides a hall device module having high sensitivity by generating high hall voltage.

Another aspect of the present invention provides a hall device module capable of additionally removing an offset generated due to a mismatch between first and second hall devices.

According to an aspect of the present invention, there is provided a hall device module including: a first hall device having a first pair of terminals for excitation and a pair of output terminals; and a second hall device having a second pair of terminals for excitation and a pair of output terminals, wherein the first and second hall devices have the same equivalent circuit, the second hall device is disposed to be rotated by a predetermined angle with relation to the first hall device, a first terminal of the first pair of terminals is interconnected to a first terminal of the second pair of terminals to receive driving power for excitation, a second terminal of the first pair of terminals is interconnected to a second terminal of the second pair of terminals and is grounded, terminals outputting a positive component, which is a voltage rising according to an applied external magnetic field, among the pair of output terminals of the first hall device and the pair of output terminals of the second hall device, are interconnected, and terminals outputting a negative component, which is a voltage falling according to the applied external magnetic field, are interconnected to thereby remove an offset.

The predetermined angle may be +90 degrees or −90 degrees.

The hall device module may further include a switch module performing complementary switching such that a DC component of a first voltage outputted from a first connecting portion between the terminals outputting the positive component becomes identical to a DC component of a second voltage outputted from a second connecting portion between the terminals outputting the positive component.

The switch module may include a first switch having one end connected to the first connecting portion and the other end connected to a first output terminal; a second switch having one end connected to the second connecting portion and the other end connected to a second output terminal; a third switch having one end connected to the first connecting portion and the other end connected to the second output terminal; and a fourth switch having one end connected to the second connecting portion and the other end connected to the first output terminal; the first and second switches being opened and closed according to a first clock and the third and fourth switches being opened and closed according to a second clock complementary to the first clock.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view showing the configuration of a hall device module equipped with interconnected double hall devices according to an exemplary embodiment of the present invention;

FIG. 2 is a view showing an equivalent circuit of a hall device module equipped with interconnected double hall devices according to an exemplary embodiment of the present invention;

FIGS. 3A and 3B are views showing a voltage waveform outputted from a first connecting portion and a second connecting portion of interconnected double hall devices, assuming that there is a difference in a manufacturing process between a first hall device and a second hall device; and

FIGS. 4A to 4D are views showing an output waveform from a first output terminal and a second output terminal of a hall device module when a switch module according to an exemplary embodiment of the present invention is applied, assuming that there is a difference in a manufacturing process between a first hall device and a second hall device.

### DETAILED DESCRIPTION OF THE PREFERRED EMBODIMENT

Exemplary embodiments of the present invention will now be described in detail with reference to the accompanying drawings.

The present invention should not be limited to the embodiments set forth herein and the embodiments may be used to assist in understanding the technical idea of the present invention. Like reference numerals designate like components having substantially the same constitution and function in the drawings of the present invention.

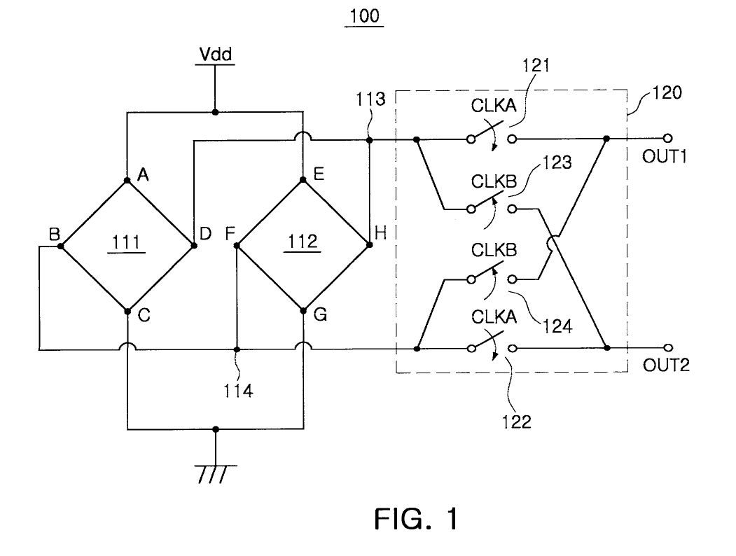

FIG. 1 is a view showing the configuration of a hall device module equipped with interconnected double hall devices according to an exemplary embodiment of the present invention. The hall device module may include interconnected double hall devices 111 and 112 disposed adjacent to each other at a predetermined interval therebetween on the same plane and a switch module 120 connected to output terminals of the interconnected double hall devices 111 and 112.

Referring to FIG. 1, a first hall device 111 includes a first pair of excitation terminals A and C and a second pair of output terminals B and D, and a second hall device 112 includes a third pair of excitation terminals E and G and a fourth pair of output terminals F and H.

The terminal A of the first hall device 111 is interconnected to the terminal E of the second hall device 112 to receive driving power Vdd for excitation of the hall device. Meanwhile, the terminal C of the first hall device 111 is grounded in the state in which it is interconnected to the terminal G of the second hall device 112. In addition, the terminal B of the first hall device 111 is interconnected to the terminal F of the second hall device 112, and the terminal D of the first hall device 111 is interconnected to the terminal H of the second hall device 112.

A first connecting portion 113 between the terminal A of the first hall device 111 and the terminal E of the second hall device 112, and a second connecting portion 114 between the terminal B of the first hall device 111 and the terminal H of the second hall device 112 are connected to an input terminal of the switch module 120.

Meanwhile, the switch module 120 may include a first switch 121 having one end connected to the first connecting portion 113 and the other end connected to a first output terminal OUT1, a second switch 122 having one end connected to the second connecting portion 114 and the other end connected to a second output terminal OUT2, a third switch 123 having one end connected to the first connecting portion 113 and the other end connected to the second output terminal OUT1, and a fourth switch 124 having one end connected to the second connecting portion 114 and the other end connected the to first output terminal OUT1. The first switch 121 and the second switch 122 are opened and closed according to a first clock CLKA, and the third switch 123 and the fourth switch 124 are opened and closed according to a second clock CLKB, wherein the first clock CLKA and the second clock CLKB are configured to complementarily operate.

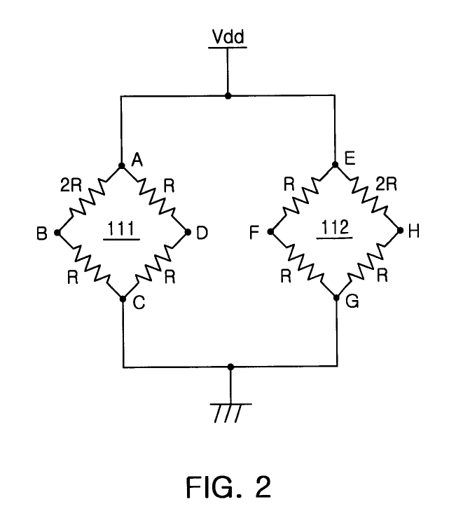

Meanwhile, FIG. 2 is a view showing an equivalent circuit of a hall device module equipped with interconnected double hall devices according to an exemplary embodiment of the present invention.

Hereinafter, an operational principle of offset removal through interconnected double hall devices will be described in detail with reference to FIGS. 1 and 2.

As shown in FIG. 2, assuming that the first hall device 111 and the second hall device 112 are manufactured under the same condition to have the same offset, the individual hall devices 111 and 112 does not have the same resistance and includes resistance 2R (as an example) in addition to resistance R. Herein, it is assumed that the second hall device 112 is a copy of the first hall device 111. When the driving power Vdd is applied to the terminals A and C of the first hall device 111 and the terminals E and G of the second hall device 112 and a magnetic field is applied from the outside, hall voltages at the terminals B and D of the first hall device 111 and the terminals F and H of the second hall device 112 may be represented by Equation 1 below.

$${V}_{B} = \frac{1}{3} Vdd , \\ {V}_{D} = \frac{1}{2} Vdd , \\ {V}_{F} = \frac{1}{2} Vdd , \\ {V}_{H} = \frac{1}{3} Vdd , \qquad Equation 1$$

Herein, V_{B} indicates the hall voltage at the terminal B; V_{D} indicates the hall voltage at the terminal D; V_{F} indicates the hall voltage at the terminal F; and V_{H} indicates the hall voltage at the terminal H.

At this time, as shown in FIG. 1, the terminal D of the first hall device 111 outputting a positive component, that is, voltage rising according to the magnetic field is interconnected to the terminal H of the second hall device 112 outputting a negative component, that is, voltage falling according to the magnetic field. On the contrary, the terminal B of the first hall device 111 outputting a negative component, that is, voltage falling according to the magnetic field is interconnected to the terminal F of the second hall device 112 outputting a positive component, that is, voltage rising according to the magnetic field. Accordingly, a hall voltage at the first connecting portion 113 between the terminals D and H outputting the positive component and a hall voltage at the second connecting portion 114 between the terminals B and F outputting the negative component may be represented by Equation 2 below.

$${V}_{HP} = \frac{1}{3} Vdd + \frac{1}{2} Vdd = \frac{5}{6} Vdd , \\ {V}_{HN} = \frac{1}{2} Vdd + \frac{1}{3} Vdd = \frac{5}{6} Vdd \qquad Equation 2$$

Accordingly, it may be appreciated that an offset component generated from the hall devices 111 and 112 may be removed. Moreover, according to an exemplary embodiment of the present invention, since modulation is performed after the offset is removed, the hall voltage generated during one period T may be approximately two times larger than that of a case of using only one hall device.

More specifically, in the case of removing the offset by a spinning current scheme using only one hall device, a hall voltage of Vdd/3 is generated during a half period (T/2) and a hall voltage of Vdd/2 is generated during the remaining half period (T/2), such that an average hall voltage during one period becomes 5 Vdd/12. On the other hand, in the case of the embodiment of the present invention, a hall voltage of 5 Vdd/6 is generated during a half period (T/2) and a hall voltage of 5 Vdd/6 is generated during the remaining half period (T/2), such that an average hall voltage during one period becomes 5 Vdd/6. Accordingly, it may be appreciated that the hall voltage of the embodiment of the present invention may be approximately two times higher than that of the existing spinning current scheme. In addition, as described above, according to the exemplary embodiment of the present invention, since the offset may be removed through the interconnection of the two hall devices, there is no need to perform separate modulation or use a separate switch.

Meanwhile, unlike the above-mentioned case, the equivalent circuits of the first hall device 111 and the second hall device 112 may not be the same in an actual manufacturing process. As a result, the offset may not be completely removed by a method using the spinning current as shown in FIG. 1. Accordingly, according to another exemplary embodiment of the present invention, the switch module 120 for modulation may be further connected to the output terminals of the interconnected double hall devices 111 and 112. A detailed description thereof will be provided with reference to FIGS. 1 to 4.

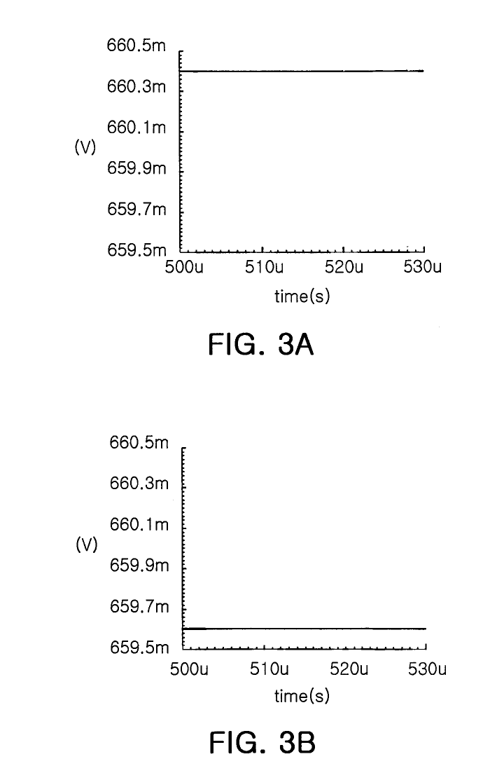

FIGS. 3A and 3B are views showing a voltage waveform outputted from the first connecting portion 111 and the second connecting portion 114 of the double hall devices when the connection is made as shown in FIG. 1, assuming that there is a difference in a manufacturing process between the first hall device 111 and the second hall device 112. An X axis indicates time, and a Y axis indicates the magnitude of voltage outputted from the connecting portions (the first connecting portion 113 in FIG. 3A and the second connecting portion 114 in FIG. 3B).

As shown in FIGS. 3A and 3B, although the first hall device 111 and the second hall device 112 are manufactured under the same condition, the first hall device 111 and the second hall device 112 may have different offsets from each other. Accordingly, it is assumed that a 660.4 mV voltage as shown in FIG. 3A is outputted from the first connecting portion 113, a 659.6 mV voltage as shown in FIG. 3B, is outputted from the second connecting portion 114, and the offset of 0.8 mV, corresponding to the difference therebetween, is outputted. Accordingly, in order to accomplish more excellent performance even in this case, according to an exemplary embodiment of the present invention, as shown in FIG. 1, the hall device module may be further equipped with the switch module 120 in order to remove malfunction of a circuit due to the offset.

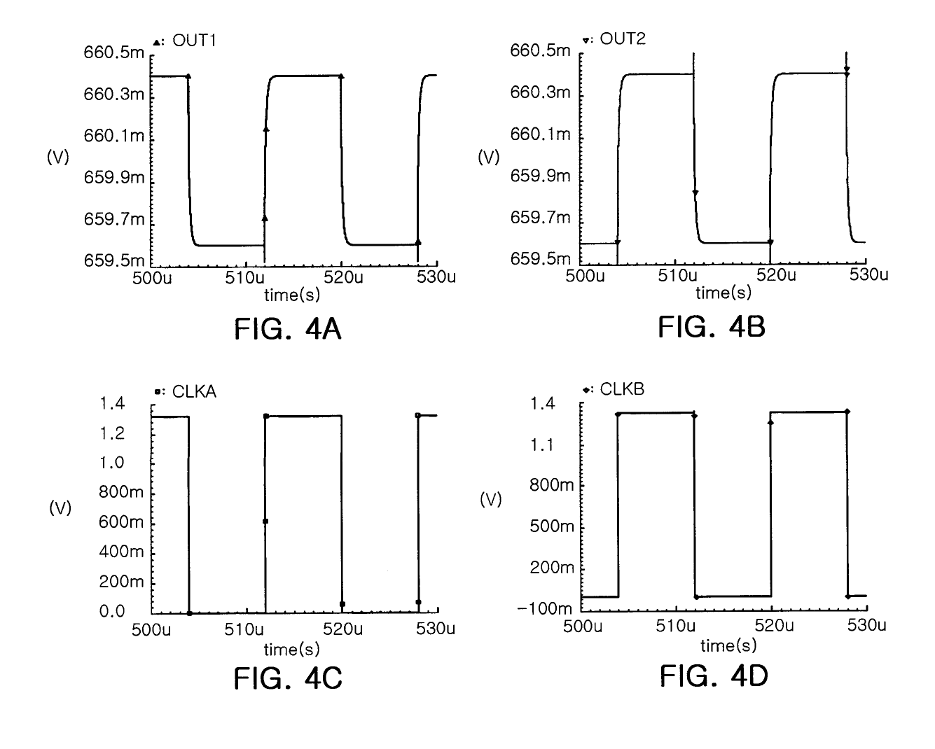

FIGS. 4A to 4D are views showing an output waveform from a first output terminal OUT1 and a second output terminal OUT2 of a hall device module when a switch module according to an exemplary embodiment of the present invention is applied, assuming that there is a difference in a manufacturing process between the first hall device and the second hall device. FIG. 4A shows voltage outputted from the first output terminal OUT1 of the switch module 120; FIG. 4B shows voltage outputted from the second output terminal OUT2 of the switch module 120; FIG. 4C shows the first clock CLKA; and FIG. 4d shows the second clock CLKB.

As shown in FIGS. 1 and 4A to 4D, when the first clock CLKA is high (H), the second clock CLKB becomes low (L). Accordingly, the voltage at the first connecting portion 113 is outputted to the first output terminal OUT1 and the voltage at the second connecting portion 114 is outputted to the second output terminal OUT2. On the contrary, when the first clock CLKA is low (L), the second clock CLKB becomes high (H). Accordingly, the voltage at the first connecting portion 113 is outputted to the second output terminal OUT2 and the voltage at the second connecting portion 114 is outputted to the first output terminal OUT1. The above-mentioned first clock CLKA and second clock CLKB are periodically repeated, and a DC signal, which is an intermediate voltage value between the voltage at the first connecting portion 113 and the voltage at the second connecting portion 114, and an AC signal, which is the offset generated due to a mismatch between the first hall device 111 and the second hall device 112, may be inputted to a signal processor (not shown) having an amplifier such a chopper amplifier as the output of the first output terminal OUT1.

An AC signal having a phase different by 180 degrees from that of the AC signal of the first output terminal OUT1 based on the DC signal, which is the intermediate voltage value between the voltage at the first connecting portion 113 and the voltage at the second connecting portion 114, is also outputted as the output of the second output terminal OUT1. Accordingly, the difference in voltage, which is the DC offset between the first connecting portion 113 and the second connecting portion 114, may be close to zero, whereby the malfunction of the signal processor (not shown) due to the DC offset may be prevented.

As set forth above, according to the exemplary embodiments of the present invention, the offset of hall devices may be removed by rotating one of two hall devices, manufactured under the same condition to be represented by the same equivalent circuit, by 90 degrees with relation to the other hall device and interconnecting these two hall devices.

In addition, since a hall voltage, in which an offset is removed, may be modulated, a high hall voltage may be generated to achieve high sensitivity.

Further, a separate switch module is added to an output terminal of a hall device module, whereby an offset, caused by a mismatch between first and second hall devices, may be additionally removed.

While the present invention has been shown and described in connection with the exemplary embodiments, it will be apparent to those skilled in the art that Modifications and variations can be made without departing from the spirit and scope of the invention as defined by the appended claims.

What is claimed is:

1. A hall device module comprising:
a first hall device having a first pair of terminals for excitation and a pair of output terminals; and
a second hall device having a second pair of terminals for excitation and a pair of output terminals,
wherein the first and second hall devices have the same equivalent circuit,
the second hall device is disposed to be rotated by a predetermined angle with relation to the first hall device,
a first terminal of the first pair of terminals is interconnected to a first terminal of the second pair of terminals to receive driving power for excitation,
a second terminal of the first pair of terminals is interconnected to a second terminal of the second pair of terminals and is grounded, and
terminals outputting a positive component, which is a voltage rising according to an applied external magnetic field, among the pair of output terminals of the first hall device and the pair of output terminals of the second hall device, are interconnected, and terminals outputting a negative component, which is a voltage falling according to the applied external magnetic field, are interconnected to thereby remove an offset.

2. The hall device module of claim 1, wherein the predetermined angle is +90 degrees or −90 degrees.

3. The hall device module of claim 1, further comprising a switch module performing complementary switching such that a DC component of a first voltage outputted from a first connecting portion between the terminals outputting the positive component becomes identical to a DC component of a second voltage outputted from a second connecting portion between the terminals outputting the positive component.

4. The hall device module of claim 3, wherein the switch module comprises:
a first switch having one end connected to the first connecting portion and the other end connected to a first output terminal;
a second switch having one end connected to the second connecting portion and the other end connected to a second output terminal;
a third switch having one end connected to the first connecting portion and the other end connected to the second output terminal; and
a fourth switch having one end connected to the second connecting portion and the other end connected to the first output terminal,
wherein the first and second switches are opened and closed according to a first clock, and
the third and fourth switches are opened and closed according to a second clock complementary to the first clock.
